(19) United States
(12) Patent Application Publication
(10) Pub. No.: US 2022/0345108 A1
(43) Pub. Date: Oct. 27, 2022

(54) ACOUSTIC WAVE DEVICE

(71) Applicant: Murata Manufacturing Co., Ltd., Nagaokakyo-shi (JP)

(72) Inventor: Sho NAGATOMO, Nagaokakyo-shi (JP)

(21) Appl. No.: 17/863,457

(22) Filed: Jul. 13, 2022

Related U.S. Application Data
(63) Continuation of application No. PCT/JP2021/000374, filed on Jan. 7, 2021.

(30) Foreign Application Priority Data
Jan. 24, 2020 (JP) 2020-010161

(51) Int. Cl. H03H 9/145; H03H 9/25

(52) U.S. Cl. CPC H03H 9/14544; H03H 9/25

(57) ABSTRACT

An acoustic wave device includes a piezoelectric substrate and an IDT electrode. In the IDT electrode, at least one electrode finger includes a first portion and a second portion in an intersection region. The first portion is in direct contact with the piezoelectric substrate. The second portion is on the first portion such that a space in at least a portion of a central portion of the intersection region in the first portion is provided. A thickness of the first portion is smaller than a thickness of a busbar. A sum of the thickness of the first portion in a portion where the second portion is present and a thickness of the second portion is thicker than the thickness of the first portion in a portion where the second portion is not present.

### CROSS REFERENCE TO RELATED APPLICATIONS

This application claims the benefit of priority to Japanese Patent Application No. 2020-010161 filed on Jan. 24, 2020 and is a Continuation Application of PCT Application No. PCT/JP2021/000374 filed on Jan. 7, 2021. The entire contents of each application are hereby incorporated herein by reference.

### BACKGROUND OF THE INVENTION

### 1. Field of the Invention

The present invention relates to acoustic wave devices, and more particularly, to an acoustic wave device including interdigital transducer (IDT) electrodes.

### 2. Description of the Related Art

International Publication No. 2012/086639 describes an existing acoustic wave device. The acoustic wave device described in International Publication No. 2012/086639 includes a piezoelectric film (piezoelectric substrate) and an IDT electrode. In the acoustic wave device described in International Publication No. 2012/086639, the IDT electrode is formed on one surface of the piezoelectric film.

In the existing acoustic wave device described in International Publication No. 2012/086639, since the main portion (intersection region) of the IDT electrode is in direct contact with the piezoelectric film (piezoelectric substrate), mechanical reflection of an acoustic wave by the IDT electrode can be obtained. However, when the volume (thickness) of the IDT electrode is increased to increase the Q value at a resonant frequency of the acoustic wave device, the mass of electrode fingers in direct contact with the piezoelectric film in the central portion of the intersection region of the IDT electrode increases. Therefore, there is a problem in that material loss increases and the Q value at an anti-resonant frequency of the acoustic wave device decreases. That is, it is difficult to improve both the Q value at the resonant frequency and the Q value at the anti-resonant frequency.

On the other hand, when the main portion (intersection region) of the IDT electrode is not in direct contact with the piezoelectric film (piezoelectric substrate), a decrease in the Q value at the anti-resonant frequency due to an increase in the volume (thickness) of the IDT electrode is less likely to occur, but mechanical reflection of an acoustic wave by the IDT electrode is insufficient. As such, even when the volume (thickness) of the IDT electrode is increased to increase the Q value at the resonant frequency of the acoustic wave device, the Q value at the anti-resonant frequency of the acoustic wave device decreases as described above. Therefore, also in this case, it is difficult to improve both the Q value at the resonant frequency and the Q value at the anti-resonant frequency.

### SUMMARY OF THE INVENTION

Preferred embodiments of the present invention provide acoustic wave devices that are each able to improve both of a Q value at a resonant frequency and a Q value at an anti-resonant frequency.

An acoustic wave device according to a preferred embodiment of the present invention includes a piezoelectric substrate and an IDT electrode. The IDT electrode is on the piezoelectric substrate. The IDT electrode includes a plurality of electrode fingers and a busbar. The plurality of electrode fingers are connected to the busbar. At least one electrode finger of the plurality of electrode fingers includes a first portion and a second portion in an intersection region where the plurality of electrode fingers overlap when viewed from a propagation direction of an acoustic wave in the piezoelectric substrate. The first portion is in direct contact with the piezoelectric substrate. The second portion is laminated on the first portion. The second portion is located on the first portion such that a space in at least a portion of a central portion of the intersection region in the first portion is provided. A thickness of the first portion is thinner than a thickness of the busbar. A sum of a thickness of the first portion in a portion where the second portion is present and a thickness of the second portion is thicker than a thickness of the first portion in a portion where the second portion is not present.

According to preferred embodiments of the present invention, both the Q value at the resonant frequency and the Q value at the anti-resonant frequency are able to be improved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view of an acoustic wave device according to Preferred Embodiment 1 of the present invention.

FIG. 2 is a plan view of the acoustic wave device according to Preferred Embodiment 1 of the present invention.

FIG. 3A is a graph illustrating characteristics of the acoustic wave device according to Preferred Embodiment 1 of the present invention. FIG. 3B is a graph illustrating characteristics of an acoustic wave device of a comparative example.

FIG. 4A is a cross-sectional view of an acoustic wave device according to Modification 1 of Preferred Embodiment 1 of the present invention. FIG. 4B is a cross-sectional view of an acoustic wave device according to Modification 2 of Preferred Embodiment 1 of the present invention. FIG. 4C is a cross-sectional view of an acoustic wave device according to Modification 3 of Preferred Embodiment 1 of the present invention. FIG. 4D is a cross-sectional view of an acoustic wave device according to Modification 4 of Preferred Embodiment 1 of the present invention.

FIG. 5 is a cross-sectional view of an acoustic wave device according to Modification 5 of Preferred Embodiment 1 of the present invention.

FIG. 6 is a plan view of an acoustic wave device according to Modification 6 of Preferred Embodiment 1 of the present invention.

FIG. 7 is a cross-sectional view of an acoustic wave device according to Preferred Embodiment 2 of the present invention.

FIG. 8 is a cross-sectional view of an acoustic wave device according to Preferred Embodiment 3 of the present invention.

FIG. 9 is a cross-sectional view of an acoustic wave device according to Preferred Embodiment 4 of the present invention.

### DETAILED DESCRIPTION OF THE PREFERRED EMBODIMENTS

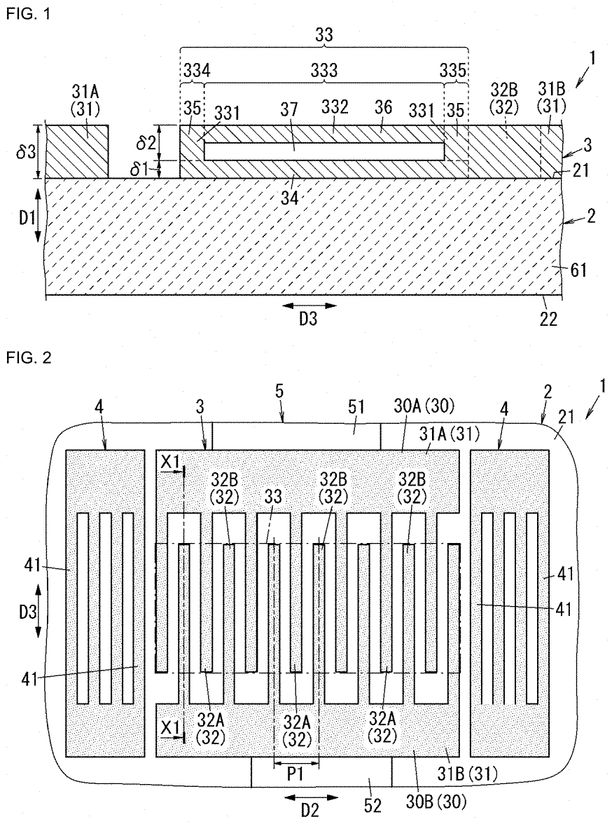

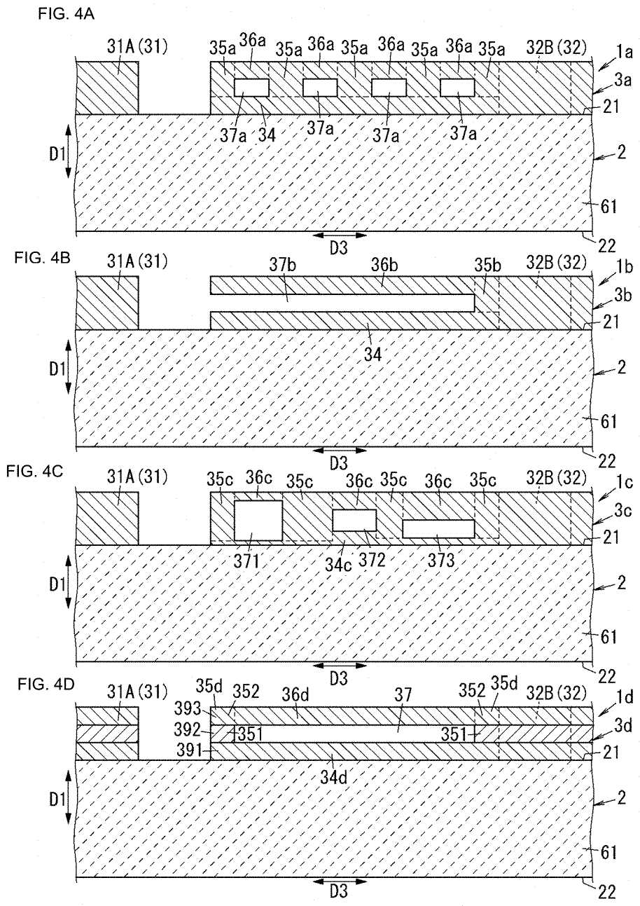

Hereinafter, acoustic wave devices according to Preferred Embodiments 1 to 4 will be described with reference to the drawings. FIG. 1, FIG. 2, FIGS. 4A to 4D, and FIG. 5 to FIG. 9 referred to in the following preferred embodiments and the like are schematic diagrams, and ratios of sizes and thicknesses of components in the diagrams do not necessarily reflect actual dimensional ratios. Note that FIG. 1 is a cross-sectional view taken along a line X1-X1 in FIG. 2.

### Preferred Embodiment 1

### (1) Acoustic Wave Device

An overall configuration of an acoustic wave device 1 according to Preferred Embodiment 1 of the present invention will be described with reference to the drawings.

As illustrated in FIG. 1 and FIG. 2, the acoustic wave device 1 according to Preferred Embodiment 1 includes a piezoelectric substrate 2 and an interdigital transducer (IDT) electrode 3. The IDT electrode 3 is provided on the piezoelectric substrate 2. The IDT electrode 3 includes two electrodes 30.

In addition, the acoustic wave device 1 further includes two reflectors 4. The two reflectors 4 are provided on the piezoelectric substrate 2. The two reflectors 4 are located on one side and the other side of the IDT electrode 3 one by one in a direction (second direction D2) along a propagation direction of an acoustic wave of the acoustic wave device 1. In other words, the IDT electrode 3 is located between the two reflectors 4 in the second direction D2.

In addition, the acoustic wave device 1 further includes a wiring portion 5. The wiring portion 5 is provided on the piezoelectric substrate 2 and is connected to the IDT electrode 3.

In addition, the acoustic wave device 1 further includes a protective film (not illustrated). The protective film covers the IDT electrode 3, each of the reflectors 4, and the wiring portion 5 on the piezoelectric substrate 2.

In the acoustic wave device 1, one IDT electrode 3 is provided on the piezoelectric substrate 2, but the number of IDT electrodes 3 is not limited to one and may be plural. In a case where the acoustic wave device 1 includes a plurality of the IDT electrodes 3, for example, a plurality of surface acoustic wave resonators including the plurality of IDT electrodes 3 may be electrically connected to define a band-pass filter.

### (2) Components of Acoustic Wave Device

Hereinafter, components of the acoustic wave device 1 according to Preferred Embodiment 1 will be described with reference to the drawings.

### (2.1) Piezoelectric Substrate

In the acoustic wave device 1 according to Preferred Embodiment 1, the piezoelectric substrate 2 is a piezoelectric substrate 61. The material of the piezoelectric substrate 61 is, for example, lithium tantalate (LiTaO₃). The piezoelectric substrate 61 is made of, for example, a Γ° Y-cut X-propagation LiTaO₃ piezoelectric single crystal. When three crystal axes of a LiTaO₃ piezoelectric single crystal are defined as an X-axis, a Y-axis, and a Z-axis, the Γ° Y-cut X-propagation LiTaO₃ piezoelectric single crystal is, for example, a LiTaO₃ single crystal obtained by cutting the LiTaO₃ piezoelectric single crystal along a plane having, as a normal line, an axis that is rotated by Γ° about the X-axis as the center axis from the Y-axis in a Z-axis direction, and a surface acoustic wave in the single crystal being propagating in an X-axis direction. The cut angle of the piezoelectric substrate 61 is Γ=θ+90° when the cut angle is Γ [°] and the Euler angles of the piezoelectric substrate are (φ, Γ, ψ). However, Γ and Γ±180×n are synonymous (crystallographically equivalent). Here, n is a natural number. The piezoelectric substrate 61 is not limited to the Γ° Y-cut X-propagation LiTaO₃ piezoelectric single crystal, and may be, for example, a Γ° Y-cut X-propagation LiTaO₃ piezoelectric ceramics.

The piezoelectric substrate 2 includes a first main surface 21 and a second main surface 22. The first main surface 21 and the second main surface 22 face each other in a thickness direction (first direction D1) of the piezoelectric substrate 2. The piezoelectric substrate 2 has a rectangular or substantially rectangular shape in a plan view from the thickness direction (first direction D1) of the piezoelectric substrate 2, but is not limited thereto, and may have a square or substantially square shape, for example.

The thickness of the piezoelectric substrate 61 is, for example, less than about 2 λ, where λ is a wavelength determined by a pitch P1 of a plurality of electrode fingers 32 of the IDT electrode 3. As described above, the Q value of the acoustic wave device 1 can be further improved.

The material of the piezoelectric substrate 61 is not limited to lithium tantalate (LiTaO₃), and may be, for example, lithium niobate (LiNbO₃), zinc oxide (ZnO), aluminum nitride (AlN), or lead zirconate titanate (PZT). In a case where the piezoelectric substrate 61 is made of, for example, a Y-cut X-propagation LiNbO₃ piezoelectric single crystal or a piezoelectric ceramics, the acoustic wave device 1 can use an SH mode having a higher coupling coefficient. The single crystal material and the cut angle of the piezoelectric substrate 61 may be appropriately determined according to, for example, required specifications of the filter (filter characteristics such as, for example, bandpass characteristics, attenuation characteristics, temperature characteristics, and band width).

### (2.2) IDT Electrode

As illustrated in FIG. 1 and FIG. 2, the IDT electrode 3 is provided on the piezoelectric substrate 2. More specifically, the IDT electrode 3 is provided on the first main surface 21 of the piezoelectric substrate 2.

As illustrated in FIG. 2, the IDT electrode 3 includes two busbars 31 and two groups of the electrode fingers 32. More specifically, the IDT electrode 3 includes a first electrode 30A and a second electrode 30B. Each of the first electrode 30A and the second electrode 30B has conductivity. The first electrode 30A and the second electrode 30B are separated from each other and are electrically insulated from each other. Note that as illustrated in FIG. 6, the IDT electrode 3 may include one or a plurality of dummy electrode fingers 38. The dummy electrode finger 38 is not a necessary component, and is not necessarily provided.

As illustrated in FIG. 2, the first electrode 30A has a comb shape in a plan view from the thickness direction (first direction D1) of the piezoelectric substrate 2. The first electrode 30A includes a first busbar 31A and a plurality of first electrode fingers 32A. The first busbar 31A is a conductor portion for making the plurality of first electrode fingers 32A have the same potential (equal potential). As illustrated in FIG. 6, in a case where the IDT electrode 3 includes the dummy electrode fingers 38, the first electrode 30A includes the first busbar 31A, the plurality of first electrode fingers 32A, and a plurality of first dummy electrode fingers 38A.

As illustrated in FIG. 2, the second electrode 30B has a comb shape in a plan view from the thickness direction (first direction D1) of the piezoelectric substrate 2. The second electrode 30B includes a second busbar 31B and a plurality of second electrode fingers 32B. The second busbar 31B is a conductor portion for making the plurality of second electrode fingers 32B have the same potential (equal potential). As illustrated in FIG. 6, in the case where the IDT electrode 3 includes the dummy electrode fingers 38, the second electrode 30B includes the second busbar 31B, the plurality of second electrode fingers 32B, and a plurality of second dummy electrode fingers 38B.

As illustrated in FIG. 2, the plurality of first electrode fingers 32A are connected to the first busbar 31A and extend toward the second busbar 31B side. The plurality of first electrode fingers 32A are integrally provided with the first busbar 31A and are separated from the second busbar 31B.

As illustrated in FIG. 2, the plurality of second electrode fingers 32B are connected to the second busbar 31B and extend toward the first busbar 31A side. The plurality of second electrode fingers 32B are integrally provided with the second busbar 31B and are separated from the first busbar 31A.

In addition, the IDT electrode 3 illustrated in FIG. 1 and FIG. 2 is, for example, a normal IDT electrode. Hereinafter, the IDT electrode 3 will be described in more detail.

The first busbar 31A and the second busbar 31B of the IDT electrode 3 have an elongated shape whose longitudinal direction is the second direction D2. In the IDT electrode 3, the first busbar 31A and the second busbar 31B face each other in a third direction D3. The second direction D2 is a direction orthogonal or substantially orthogonal to the thickness direction of the piezoelectric substrate 2 (first direction D1). The third direction D3 is a direction orthogonal or substantially orthogonal to both the thickness direction (first direction D1) of the piezoelectric substrate 2 and the second direction D2.

The plurality of first electrode fingers 32A are connected to the first busbar 31A and extend toward the second busbar 31B. Here, the plurality of first electrode fingers 32A extend from the first busbar 31A along the third direction D3. Tips of the plurality of first electrode fingers 32A are separated from the second busbar 31B. For example, lengths and widths of the plurality of first electrode fingers 32A are the same or substantially the same as each other.

The plurality of second electrode fingers 32B are connected to the second busbar 31B and extend toward the first busbar 31A. Here, the plurality of second electrode fingers 32B extend from the second busbar 31B along the third direction D3. Tips of the plurality of second electrode fingers 32B are separated from the first busbar 31A. For example, lengths and widths of the plurality of second electrode fingers 32B are the same or substantially the same as each other. In the example of FIG. 2, the lengths and widths of the plurality of second electrode fingers 32B are the same or substantially the same as the lengths and widths of the plurality of first electrode fingers 32A, respectively.

In the IDT electrode 3, the plurality of first electrode fingers 32A and the plurality of second electrode fingers 32B are alternately arranged one by one to be spaced apart from each other in the second direction D2. Therefore, the first electrode finger 32A and the second electrode finger 32B adjacent to each other are separated from each other. A group of the electrode fingers 32 including the plurality of first electrode fingers 32A and the plurality of second electrode fingers 32B may be configured such that the plurality of first electrode fingers 32A and the plurality of second electrode fingers 32B are arranged to be spaced apart from each other in the second direction D2, and also may have a configuration in which the plurality of first electrode fingers 32A and the plurality of second electrode fingers 32B are not alternately arranged to be spaced apart from each other. For example, a region in which the first electrode finger 32A and the second electrode finger 32B are arranged one by one to be spaced apart from each other and a region in which the first electrode fingers 32A or the second electrode fingers 32B are arranged two by two in the second direction D2 may be mixed.

The IDT electrode 3 includes an intersection region 33 defined by the plurality of first electrode fingers 32A and the plurality of second electrode fingers 32B. The intersection region 33 is a region between an envelope of the tips of the plurality of first electrode fingers 32A and an envelope of the tips of the plurality of second electrode fingers 32B in the third direction D3. The IDT electrode 3 excites an acoustic wave in the piezoelectric substrate 2 in the intersection region 33.

The IDT electrode 3 is not limited to a normal IDT electrode, and may be, for example, an IDT electrode to which apodization weighting is applied or an inclined IDT electrode. In the IDT electrode to which the apodization weighting is applied, an intersecting width increases from one end portion towards the center in the propagation direction of the acoustic wave, and the intersecting width decreases from the center towards the other end portion in the propagation direction of the acoustic wave.

As illustrated in FIG. 2, the electrode finger pitch P1 of the IDT electrode 3 is defined by a distance between center lines of two adjacent first electrode fingers 32A among the plurality of first electrode fingers 32A or a distance between center lines of two adjacent second electrode fingers 32B among the plurality of second electrode fingers 32B. The distance between the center lines of two adjacent second electrode fingers 32B is equal or substantially equal to the distance between the center lines of two adjacent first electrode fingers 32A.

In the IDT electrode 3 of the acoustic wave device 1 according to Preferred Embodiment 1, the number of pairs of the first electrode fingers 32A and the second electrode fingers 32B is, for example, 100. That is, the IDT electrode 3 includes, for example, 100 first electrode fingers 32A and 100 second electrode fingers 32B.

The material of the IDT electrode 3 is an appropriate metal material such as, for example, aluminum (Al), copper (Cu), platinum (Pt), gold (Au), silver (Ag), titanium (Ti), nickel (Ni), chromium (Cr), molybdenum (Mo), or tungsten (W), or an alloy mainly including any of these metals. Further, the IDT electrode 3 may have a structure in which a plurality of metal films made of these metals or the alloy are laminated.

### (2.3) Reflector

In the acoustic wave device 1, as illustrated in FIG. 2, the two reflectors 4 are provided on the first main surface 21 of the piezoelectric substrate 2. Each of the two reflectors 4 is electrically conductive. Each of the two reflectors 4 is, for example, a short-circuit grating. Each reflector 4 reflects the acoustic wave.

Each of the two reflectors 4 includes a plurality of (for example, four in the illustrated example) electrode fingers 41, in which one ends of the plurality of electrode fingers 41 are short-circuited with each other and the other ends thereof are short-circuited with each other. In each of the two reflectors 4, the number of electrode fingers 41 is 20, as an example.

In the acoustic wave device 1, in a case where each of the reflectors 4 and the IDT electrode 3 are made of the same material and have the same or substantially the same thickness, each of the reflectors 4 and the IDT electrode 3 can be formed in the same process when manufacturing the acoustic wave device 1.

In the acoustic wave device 1 according to Preferred Embodiment 1, each of the reflectors 4 is a short-circuit grating. However, each of the reflectors 4 is not limited to a short-circuit grating, and may be, for example, an open grating, a positive/negative reflection grating, or a grating combined by the short-circuit grating and the open grating.

### (2.4) Wiring Portion

In the acoustic wave device 1, as illustrated in FIG. 2, the wiring portion 5 is provided on the first main surface 21 of the piezoelectric substrate 2. The wiring portion 5 has conductivity.

The wiring portion 5 includes a first wiring portion 51 connected to the first busbar 31A of the IDT electrode 3 and a second wiring portion 52 connected to the second busbar 31B of the IDT electrode 3. The first wiring portion 51 and the second wiring portion 52 are separated from each other and are electrically insulated from each other.

The first wiring portion 51 extends from the first busbar 31A to the side opposite to the first electrode finger 32A side. The first wiring portion 51 may partially overlap the first busbar 31A in the thickness direction (first direction D1) of the piezoelectric substrate 2, or may be integral with the first busbar 31A using the same material and the same or substantially the same thickness as the first busbar 31A.

The second wiring portion 52 extends from the second busbar 31B to the side opposite to the plurality of second electrode fingers 32B side. The second wiring portion 52 may partially overlap the second busbar 31B in the thickness direction (first direction D1) of the piezoelectric substrate 2, or may be integral with the second busbar 31B using the same material and the same or substantially the same thickness as the second busbar 31B.

The material of the first wiring portion 51 and the second wiring portion 52 is, for example, aluminum (Al), copper (Cu), platinum (Pt), or gold (Au), or an alloy mainly including any of these metals.

The acoustic wave device 1 may further include a first terminal connected to the first busbar 31A via the first wiring portion 51 and a second terminal connected to the second busbar 31B via the second wiring portion 52. In addition, the acoustic wave device 1 may further include two third wiring portions connected one by one to each of the two reflectors 4. In this case, each of the two reflectors 4 may be connected to a third terminal via at least the third wiring portion. A plurality of external connection terminals including the first terminal, the second terminal, and the third terminal is an electrode to electrically connect to, for example, a circuit board, a package mounting substrate (submount substrate), or the like in the acoustic wave device 1. In addition, the acoustic wave device 1 may further include a plurality of dummy terminals that are not electrically connected to the IDT electrode 3. The plurality of dummy terminals are terminals to increase parallelism of the acoustic wave device 1 with respect to a circuit board, a mounting substrate, or the like, and is different from a terminal to provide electrical connection. That is, the dummy terminal is a terminal to reduce or prevent the acoustic wave device 1 from being mounted on, for example, a circuit board, a mounting substrate, or the like in an inclined manner, and is not necessarily provided depending on the number and arrangement of external connection terminals, the outer peripheral shape of the acoustic wave device 1, and the like.

The first terminal is integral with the first wiring portion 51 using the same material and the same or substantially the same thickness as those of the first wiring portion 51, for example. The second terminal is integral with the second wiring portion 52 using the same material and the same or substantially the same thickness as those of the second wiring portion 52, for example. The third terminal is integral with the third wiring portion using the same material and the same or substantially the same thickness as those of the third wiring portion, for example. The third wiring portion is made of the same material and with the same or substantially the same thickness as the first wiring portion 51 and the second wiring portion 52, for example.

### (2.5) Protective Film

The protective film (not illustrated) covers the IDT electrode 3, the first wiring portion 51, the second wiring portion 52, the third wiring portion, and each of the reflectors 4 on the first main surface 21 of the piezoelectric substrate 2, and a portion of the first main surface 21 of the piezoelectric substrate 2.

The material of the protective film is, for example, silicon oxide, but is not limited thereto, and may be, for example, silicon nitride. The protective film is not limited to a single layer structure, and may be, for example, a multilayer structure including two or more layers.

In the acoustic wave device 1 according to Preferred Embodiment 1, the thickness of the protective film is thinner than the thickness of the IDT electrode 3, and the surface of the protective film has an uneven shape conforming to the shape of the base of the protective film. In the acoustic wave device 1, the surface of the protective film may be flattened into a planar shape. In addition, in the acoustic wave device 1, the thickness of the protective film may be thicker than the thickness of the IDT electrode 3, and the surface of the protective film may have an uneven shape conforming to the shape of the base of the protective film. Note that the protective film is not necessarily provided.

### (3) Structure of IDT Electrode

As described above, as illustrated in FIG. 2, the IDT electrode 3 includes the two busbars 31 and two groups of the electrode fingers 32. The plurality of electrode fingers 32 are connected to each of the busbars 31. More specifically, in the first electrode 30A, the plurality of first electrode fingers 32A are connected to the first busbar 31A, and in the second electrode 30B, the plurality of second electrode fingers 32B are connected to the second busbar 31B.

As illustrated in FIG. 1, each of the plurality of electrode fingers 32 includes a first portion 34 and two second portions 35 in the intersection region 33. The intersection region 33 is a region where the plurality of electrode fingers 32 overlap each other when viewed from the propagation direction (second direction D2) of the acoustic wave in the piezoelectric substrate 2. The first portion 34 is in direct contact with the piezoelectric substrate 2. Each of the second portions 35 is laminated on a portion of the first portion 34 that does not include at least a portion of a central portion 333 of the intersection region 33. In other words, each of the second portions 35 is located on the first portion 34 such that a space (hollow portion 37) in at least a portion of the central portion 333 of the intersection region 33 in the first portion 34 is provided. In the example of FIG. 1, the two second portions 35 are laminated on portions (tip side portion 334 and base side portion 335) different from the central portion 333. The tip side portion 334 is a portion on the distal end side of the electrode finger 32 in the intersection region 33. The base side portion 335 is a base side portion of the electrode finger 32 in the intersection region 33. The central portion 333 is a portion between the tip side portion 334 and the base side portion 335 in the intersection region 33.

In the above-described structure, a thickness δ1 of the first portion 34 is thinner than a thickness δ3 of the busbar 31. More specifically, in the first direction D1, the thickness δ1 of the first portion 34 is thinner than the thickness δ3 of the busbar 31.

Further, the sum of the thickness δ1 of the first portion 34 in the first portion 331 where the second portion 35 is present and a thickness δ2 of the second portion 35 is thicker than the thickness δ1 of the first portion 34 in the second portion 332 where the second portion 35 is not present.

As described above, it is possible to improve both the Q value at the resonant frequency and the Q value at the anti-resonant frequency.

All of the plurality of electrode fingers 32 are not limited to having the above-described structure, and only some electrode fingers 32 of the plurality of electrode fingers 32 may have the above-described structure. In short, at least one electrode finger 32 of the plurality of electrode fingers 32 may have the above-described structure.

In Preferred Embodiment 1, each of the plurality of electrode fingers 32 further includes a third portion 36. The third portion 36 extends from the second portion 35 over at least a portion of the central portion 333 of the intersection region 33 in a plan view from the thickness direction (first direction D1) of the piezoelectric substrate 2. In the present preferred embodiment, the third portion 36 extends from an end portion of the second portion 35 on the first busbar 31A side on the central portion 333 side of the intersection region 33 to an end portion of the second portion 35 on the second busbar 31B side on the central portion 333 side of the intersection region 33. The third portion 36 may extend from an end portion of the second portion 35 on the first busbar 31A side or the second busbar 31B side on the central portion 333 side of the intersection region 33 over a portion of the central portion 333 of the intersection region 33. That is, there may be a portion where the third portion 36 is not present in the central portion 333 of the intersection region 33.

In each of the electrode fingers 32 of Preferred Embodiment 1, the hollow portion 37 is defined by the first portion 34, the two second portions 35, and the third portion 36. The hollow portion 37 is a space surrounded by the first portion 34, the two second portions 35, and the third portion 36.

As described above, since the volume of the electrode finger 32 can be increased by the third portion 36, the Q value at the resonant frequency can be more easily improved.

All of the plurality of electrode fingers 32 include the third portion 36, but are not limited thereto, and only some electrode fingers 32 of the plurality of electrode fingers 32 may include the third portion 36. In short, at least one electrode finger 32 of the plurality of electrode fingers 32 may include the third portion 36.

In addition, in a plan view from the thickness direction (first direction D1) of the piezoelectric substrate 2, the total area of portions between the plurality of second portions 35 is larger than the total area of the plurality of second portions 35.

As described above, the Q value at the resonant frequency and the Q value at the anti-resonant frequency can be further improved.

In each of the electrode fingers 32, the two second portions 35 are provided in outer side portions (tip side portion 334 and base side portion 335) of the central portion 333 in the intersection region 33 in the third direction D3.

As described above, since the second portions 35 become a low acoustic velocity region and a piston mode can be provided, the transverse mode ripple can be reduced or prevented.

In addition, in each of the electrode fingers 32, the second portions 35 include, for example, aluminum. As described above, the electrical conductivity of the IDT electrode 3 can be improved.

Further, in each of the electrode fingers 32, the third portion 36 includes, for example, aluminum. As described above, the electrical conductivity of the IDT electrode 3 can be improved.

### (4) Characteristics of Acoustic Wave Device

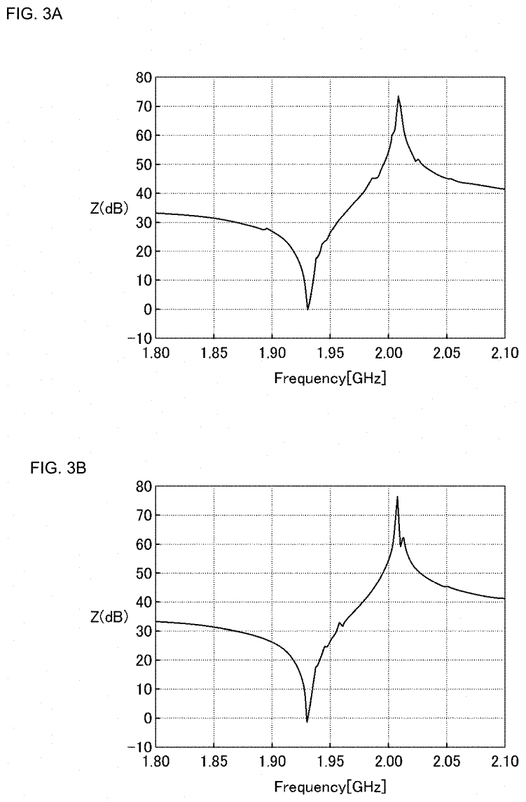

Next, impedance characteristics of the acoustic wave device 1 according to Preferred Embodiment 1 will be described with reference to FIGS. 3A and 3B. FIG. 3A shows the impedance characteristics of the acoustic wave device 1 according to Preferred Embodiment 1. That is, the impedance characteristics of the acoustic wave device 1 in which the hollow portion 37 is provided in the electrode finger 32 are shown. FIG. 3B shows the impedance characteristics of an acoustic wave device in which a hollow portion is not provided in an electrode finger as a comparative example.

As illustrated in FIGS. 3A and 3B, the acoustic wave device 1 according to Preferred Embodiment 1 can obtain the same or substantially the same impedance characteristics as those of the acoustic wave device of the comparative example. In other words, even the acoustic wave device 1 including the hollow portion 37 can obtain the impedance characteristics the same as or similar to those of an acoustic wave device not having the hollow portion 37.

### (5) Advantageous Effects

In the acoustic wave device 1 according to Preferred Embodiment 1, the first portion 34 of at least one electrode finger 32 of the plurality of electrode fingers 32 is in direct contact with the piezoelectric substrate 2. This makes it possible to obtain good mechanical reflection. As a result, it is possible to reduce or prevent deterioration of the Q value at the anti-resonant frequency.

In addition, in the acoustic wave device 1 according to Preferred Embodiment 1, the thickness δ1 of the first portion 34 is thinner than the thickness δ3 of the busbar 31, and the second portion 35 is provided in a portion (first portion 331) different from a region that does not include at least a portion of the central portion 333 of the intersection region 33. As a result, the mass added to the piezoelectric substrate 2 in the central portion 333 of the intersection region 33 can be reduced, so that the material loss can be reduced or prevented. As a result, it is possible to reduce or prevent deterioration of the Q value at the anti-resonant frequency. On the other hand, since the volume of the entire IDT electrode 3 can be increased by the busbar 31, the resistance loss can be reduced. As a result, the deterioration of the Q value at the resonant frequency can be reduced or prevented.

Furthermore, in the acoustic wave device 1 according to Preferred Embodiment 1, the sum of the thickness δ1 of the first portion 34 in the portion where the second portion 35 is present and the thickness δ2 of the second portion 35 is thicker than the thickness δ1 of the first portion 34 in the portion where the second portion 35 is not present. As a result, the volume of the entire IDT electrode 3 can be increased, and thus resistance loss can be reduced. As a result, the deterioration of the Q value at the resonant frequency can be reduced or prevented.

As described above, according to the acoustic wave device 1 of Preferred Embodiment 1, the electrode fingers 32 are in contact with the piezoelectric substrate 61 in the central portion 333 of the intersection region 33, and the volume of the electrode fingers 32 (or the volume of the IDT electrode 3) is increased in the portion of the intersection region 33 that does not include the central portion 333, so that both the Q value at the resonant frequency and the Q value at the anti-resonant frequency can be improved.

In the acoustic wave device 1 according to Preferred Embodiment 1, at least one electrode finger 32 is further provided with the third portion 36. Accordingly, the volume of the entire IDT electrode 3 can be further increased, and thus the resistance loss can be further reduced. As a result, the Q value at the resonant frequency can be further improved.

In the acoustic wave device 1 according to Preferred Embodiment 1, the total area of the portions between the plurality of second portions 35 in the plane including the second direction D2 and the third direction D3 is larger than the total area of the plurality of second portion 35. Accordingly, it is possible to further improve the Q value at the resonant frequency and the Q value at the anti-resonant frequency.

In the acoustic wave device 1 according to Preferred Embodiment 1, the second portion 35 is provided in the edge portion (the tip side portion 334). As a result, the second portion 35 becomes a low acoustic velocity region and the piston mode can be provided, so that the transverse mode ripple can be reduced or prevented.

In the acoustic wave device 1 according to Preferred Embodiment 1, the second portion 35 includes, for example, aluminum. Thus, the electrical conductivity of the IDT electrode 3 can be improved.

In the acoustic wave device 1 according to Preferred Embodiment 1, the thickness of the piezoelectric substrate 2 is, for example, less than about 2 λ, where λ is the wavelength of the acoustic wave determined by the pitch P1 of the electrode fingers 32. Accordingly, the Q value of the acoustic wave device 1 can be further improved.

### (6) Modification

Hereinafter, modifications of Preferred Embodiment 1 will be described.

As Modification 1 of Preferred Embodiment 1, an acoustic wave device 1a may include an IDT electrode 3a as illustrated in FIG. 4A. Each of the electrode fingers 32 in the IDT electrode 3a includes the first portion 34, a plurality of (for example, five in the illustrated example) second portions 35a, and a plurality of (for example, four in the illustrated example) third portions 36a. A plurality of (for example, four in the illustrated example) hollow portions 37a are provided in each of the electrode fingers 32. Each of the hollow portions 37a is surrounded by the first portion 34, two second portions 35a, and the third portion 36a.

As Modification 2 of Preferred Embodiment 1, an acoustic wave device 1b may include an IDT electrode 3b as illustrated in FIG. 4B. Each of the electrode fingers 32 in the IDT electrode 3b includes the first portion 34, one second portion 35b, and one third portion 36b. One hollow portion 37b is provided in each of the electrode fingers 32. The hollow portion 37b is surrounded by the first portion 34, one second portion 35b, and one third portion 36b. In the hollow portion 37b, the distal end side of the electrode finger 32 is opened in the third direction D3.

As Modification 3 of Preferred Embodiment 1, an acoustic wave device 1c may include an IDT electrode 3c as illustrated in FIG. 4C. Each of the electrode fingers 32 in the IDT electrode 3c includes a first portion 34c, a plurality of (for example, four in the illustrated example) second portions 35c, and a plurality of (for example, three in the illustrated example) third portions 36c. A plurality of (for example, three in the illustrated example) hollow portions 371 to 373 are provided in each of the electrode fingers 32. The hollow portion 371, the hollow portion 372, and the hollow portion 373 are spaces having different lengths in both the first direction D1 and the third direction D3. Each of the plurality of hollow portions 371 to 373 is surrounded by the first portion 34c, two second portions 35c, and one third portion 36c.

As Modification 4 of Preferred Embodiment 1, an acoustic wave device 1d may include an IDT electrode 3d as illustrated in FIG. 4D. Each of the electrode fingers 32 in the IDT electrode 3d has a three-layer structure. Each of the electrode fingers 32 includes a lower layer 391 corresponding to a first portion 34d, an intermediate layer 392 corresponding to a lower portion 351 of each second portion 35d, and an upper layer 393 corresponding to an upper portion 352 of each second portion 35d and a third portion 36d. The lower layer 391, the intermediate layer 392, and the upper layer 393 are made of materials different from each other. The lower layer 391 and the upper layer 393 may be made of the same material.

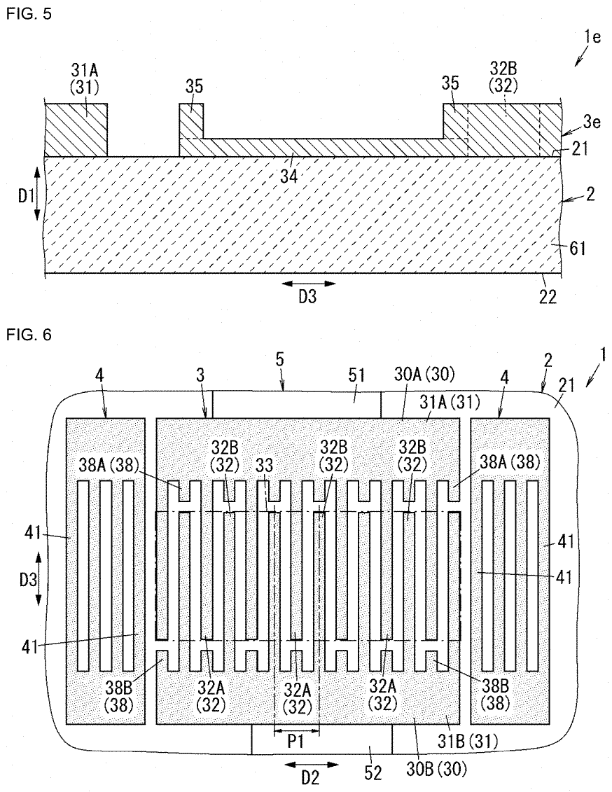

As Modification 5 of Preferred Embodiment 1, an acoustic wave device 1e may include an IDT electrode 3e as illustrated in FIG. 5. Each of the electrode fingers 32 in the IDT electrode 3e does not include the third portion 36 (see FIG. 1). That is, each of the electrode fingers 32 may be defined by the first portion 34 and the plurality of (for example, two in the illustrated example) second portions 35.

The acoustic wave devices 1a to 1e according to the above-described modifications also have the same or substantially the same or substantially the same advantageous effects as those of the acoustic wave device 1 according to Preferred Embodiment 1.

### Preferred Embodiment 2

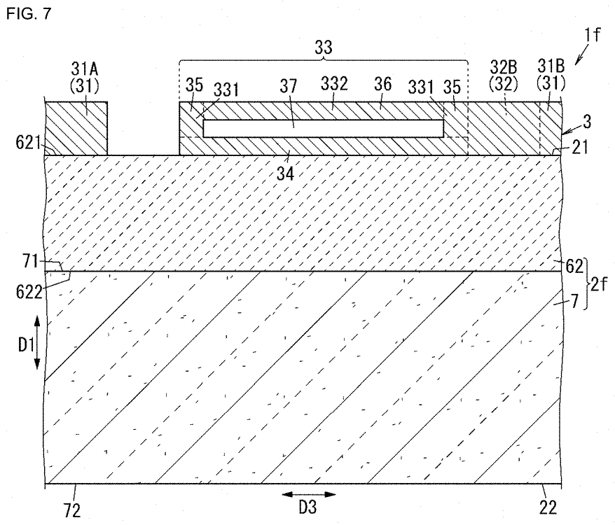

As illustrated in FIG. 7, an acoustic wave device 1f according to Preferred Embodiment 2 of the present invention is different from the acoustic wave device 1 according to Preferred Embodiment 1 (see FIG. 1) in that the acoustic wave device 1f includes a piezoelectric layer 62 and a support substrate 7. In the acoustic wave device 1f according to Preferred Embodiment 2, the same or corresponding components as those of the acoustic wave device 1 according to Preferred Embodiment 1 are denoted by the same reference numerals, and description thereof will be omitted.

### (1) Configuration

As illustrated in FIG. 7, the acoustic wave device 1f according to Preferred Embodiment 2 includes a piezoelectric substrate 2f and an IDT electrode 3. In other words, the acoustic wave device 1f according to Preferred Embodiment 2 includes the piezoelectric substrate 2f, instead of the piezoelectric substrate 2 of Preferred Embodiment 1 (see FIG. 1).

### (1.1) Piezoelectric Substrate

The piezoelectric substrate 2f of Preferred Embodiment 2 is not the piezoelectric substrate 61 like the piezoelectric substrate 2 of Preferred Embodiment 1 but is a laminated substrate. Specifically, the piezoelectric substrate 2f includes the piezoelectric layer 62 and the support substrate 7. The support substrate 7 is laminated on the piezoelectric layer 62.

### (1.2) Support Substrate

As illustrated in FIG. 7, the support substrate 7 includes a first main surface 71 and a second main surface 72 that face each other. The first main surface 71 and the second main surface 72 face each other in a thickness direction of the piezoelectric substrate 2f (first direction D1). The support substrate 7 has, for example, a rectangular or substantially rectangular shape in a plan view from the thickness direction (first direction D1) of the piezoelectric substrate 2f. The support substrate 7 is not limited to a rectangular or substantially rectangular shape, and may be, for example, a square or substantially square shape.

In the support substrate 7, an acoustic velocity of a bulk wave propagating through the support substrate 7 is higher than an acoustic velocity of an acoustic wave propagating through the piezoelectric layer 62. Here, the bulk wave propagating through the support substrate 7 is a bulk wave having the lowest acoustic velocity among a plurality of bulk waves propagating through the support substrate 7.

The support substrate 7 is, for example, a silicon substrate. The thickness of the support substrate 7 is preferably, for example, equal to or more than about 10 λ (λ: the wavelength of the acoustic wave determined by the electrode finger pitch P1) μm and equal to or less than about 180 μm, for example, about 120 μm. In a case where the support substrate 7 is a silicon substrate, a plane orientation of the first main surface 71 of the support substrate 7 is, for example, a (100) plane, but is not limited thereto, and may be, for example, a (110) plane, a (111) plane, or the like. A propagation orientation of the acoustic wave can be set without being restricted by the plane orientation of the first main surface 71 of the support substrate 7.

The support substrate 7 is not limited to a silicon substrate. The support substrate 7 may include, for example, at least one material selected from the group consisting of silicon, aluminum nitride, aluminum oxide, silicon carbide, silicon nitride, sapphire, lithium tantalate, lithium niobate, quartz, alumina, zirconia, cordierite, mullite, steatite, forsterite, magnesia, and diamond.

### (1.3) Piezoelectric Layer

As illustrated in FIG. 7, the piezoelectric layer 62 includes a first main surface 621 and a second main surface 622 that face each other. The first main surface 621 and the second main surface 622 face each other in the thickness direction of the piezoelectric substrate 2f (first direction D1).

The piezoelectric layer 62 is made of, for example, a Γ° Y-cut X-propagation LiTaO₃ piezoelectric single crystal. When three crystal axes of a LiTaO₃ piezoelectric single crystal are defined as an X-axis, a Y-axis, and a Z-axis, the Γ° Y-cut X-propagation LiTaO₃ piezoelectric single crystal is a LiTaO₃ single crystal obtained by cutting the LiTaO₃ piezoelectric single crystal along a plane having, as a normal line, an axis that is rotated by Γ° about the X-axis as the center axis from the Y-axis in a Z-axis direction, and a surface acoustic wave in the single crystal being propagating in an X-axis direction. The cut angle of the piezoelectric layer 62 is, for example, Γ=θ+90° when the cut angle is Γ[°] and the Euler angles of the piezoelectric layer 62 are (φ, θ, ψ). However, Γ and Γ±180×n are synonymous (crystallographically equivalent). Here, n is a natural number. The piezoelectric layer 62 is not limited to the Γ° Y-cut X-propagation LiTaO₃ piezoelectric single crystal, and may be, for example, a Γ° Y-cut X-propagation LiTaO₃ piezoelectric ceramics.

The thickness of the piezoelectric layer 62 is, for example, equal to or less than about 3.5 λ, where λ is the wavelength of an acoustic wave determined by the electrode finger pitch P1 (see FIG. 2) of the IDT electrode 3. When the thickness of the piezoelectric layer 62 is equal to or less than about 3.5 λ, the Q value of the acoustic wave device 1f is high. In addition, by setting the thickness of the piezoelectric layer 62 to be equal to or less than about 2.5 λ, for example, the temperature coefficient of frequency (TCF) can be reduced. Furthermore, by setting the thickness of the piezoelectric layer 62 to be equal to or less than about 1.5 λ, for example, it is easy to adjust the acoustic velocity of the acoustic wave. The thickness of the piezoelectric layer 62 is not limited to equal to or less than about 3.5 λ, and may be greater than about 3.5 λ.

When the thickness of the piezoelectric layer 62 is equal to or less than about 3.5 λ, the Q value of the acoustic wave device 1f increases as described above, but a higher-order mode occurs. In the acoustic wave device 1f, a low acoustic velocity film 8 described above is provided so as to reduce the higher-order mode even when the thickness of the piezoelectric layer 62 is equal to or less than about 3.5 λ.

In the acoustic wave device 1f, modes of acoustic waves propagating through the piezoelectric layer 62 include, for example, longitudinal waves, SH waves, SV waves, or a mode in which these waves are combined. In the acoustic wave device 1f, for example, a mode having an SH wave as a main component is used as a main mode. The higher-order mode is a spurious mode generated on a higher frequency side than the main mode of the acoustic wave propagating through the piezoelectric layer 62. Whether or not the mode of the acoustic wave propagating through the piezoelectric layer 62 is the “main mode in which the main component is an SH wave” can be confirmed by analyzing the strain by analyzing the distribution of displacements by the finite element method using parameters such as the parameters (material, Euler angles, thicknesses, etc.) of the piezoelectric layer 62, the parameters (material, thicknesses, electrode finger pitch P1, etc.) of the IDT electrode 3, and the parameters (material, thicknesses, etc.) of the low acoustic velocity film 8, for example. The Euler angle of the piezoelectric layer 62 can be obtained by analysis.

The material of the piezoelectric layer 62 is not limited to lithium tantalate (LiTaO₃), and may be, for example, lithium niobate (LiNbO₃), zinc oxide (ZnO), aluminum nitride (AlN), or lead zirconate titanate (PZT). In the case where the piezoelectric layer 62 is made of, for example, a Y-cut X-propagation LiNbO₃ piezoelectric single crystal or a piezoelectric ceramics, the acoustic wave device 1f can use an SH mode having a higher coupling coefficient. Note that the single crystal material and the cut angle of the piezoelectric layer 62 may be appropriately determined in accordance with, for example, the required specifications of the filter (filter characteristics such as bandpass characteristics, attenuation characteristics, temperature characteristics, and band width).

### (2) Advantageous Effects

The acoustic wave device 1f according to Preferred Embodiment 2 has a two-layer structure including the piezoelectric layer 62 and the support substrate 7. This makes it possible to confine the acoustic wave energy in the piezoelectric layer 62 and the IDT electrode 3 in which the acoustic wave is excited, so that the Q value of the acoustic wave device 1f can be improved.

### (3) Modification

Hereinafter, modifications of Preferred Embodiment 2 will be described.

As Modification 1 of Preferred Embodiment 2, similarly to Modification 1 of Preferred Embodiment 1, each of the electrode fingers 32 of the acoustic wave device 1f may include the plurality of hollow portions 37a (see FIG. 4A).

As Modification 2 of Preferred Embodiment 2, similarly to Modification 2 of Preferred Embodiment 1, each of the electrode fingers 32 of the acoustic wave device 1f may include the hollow portion 37b in which the distal end side of the electrode finger 32 is open (see FIG. 4B).

As Modification 3 of Preferred Embodiment 2, similarly to Modification 3 of Preferred Embodiment 1, each of the electrode fingers 32 of the acoustic wave device 1f may include the hollow portions 371 to 373 having different sizes (see FIG. 4C).

As Modification 4 of Preferred Embodiment 2, similarly to Modification 4 of Preferred Embodiment 1, each of the electrode fingers 32 of the acoustic wave device 1f may include a lower layer, an intermediate layer, and an upper layer that are made of different materials from each other (see FIG. 4D).

As Modification 5 of Preferred Embodiment 2, similarly to Modification 5 of Preferred Embodiment 1, each of the electrode fingers 32 of the acoustic wave device 1f may include the first portion 34 and the plurality of second portions 35 (see FIG. 5).

The acoustic wave devices 1f according to the above-described modifications also have the same or substantially the same advantageous effects as those of the acoustic wave device 1f according to Preferred Embodiment 2.

### Preferred Embodiment 3

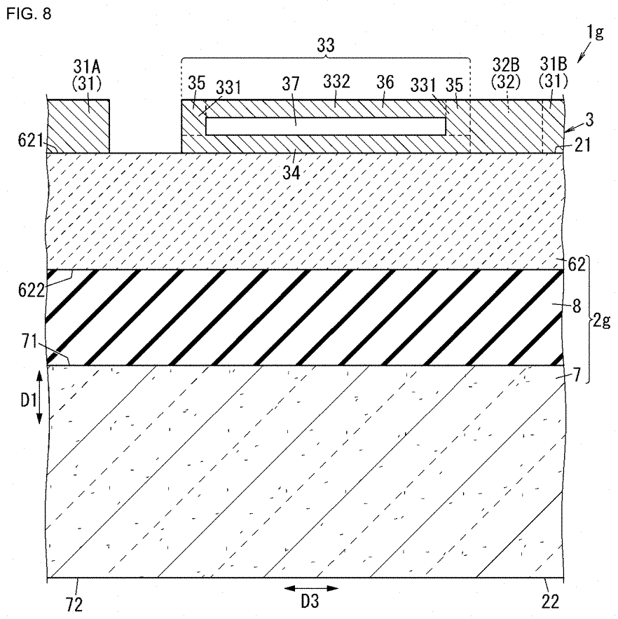

As illustrated in FIG. 8, an acoustic wave device 1g according to Preferred Embodiment 3 of the present invention is different from the acoustic wave device 1f according to Preferred Embodiment 2 (see FIG. 7) in that the acoustic wave device 1g includes the support substrate 7, the low acoustic velocity film 8, and the piezoelectric layer 62. In the acoustic wave device 1g according to Preferred Embodiment 3, the same or corresponding components as those of the acoustic wave device 1f according to Preferred Embodiment 2 are denoted by the same reference numerals, and description thereof is omitted.

### (1) Configuration

As illustrated in FIG. 8, the acoustic wave device 1g according to Preferred Embodiment 3 includes a piezoelectric substrate 2g and the IDT electrode 3. In other words, the acoustic wave device 1g according to Preferred Embodiment 3 includes the piezoelectric substrate 2g, instead of the piezoelectric substrate 2f of Preferred Embodiment 2 (see FIG. 7).

### (1.1) Piezoelectric Substrate

The piezoelectric substrate 2g of Preferred Embodiment 3 includes the support substrate 7, the low acoustic velocity film 8, and the piezoelectric layer 62. The low acoustic velocity film 8 is laminated between the piezoelectric layer 62 and the support substrate 7.

The low acoustic velocity film 8 is provided on the support substrate 7. Here, “being provided on the support substrate 7” includes a case of being provided directly on the support substrate 7 and a case of being provided indirectly on the support substrate 7. The piezoelectric layer 62 is provided on the low acoustic velocity film 8. Here, “being provided on the low acoustic velocity film 8” includes a case of being provided directly on the low acoustic velocity film 8 and a case of being provided indirectly on the low acoustic velocity film 8. Each of the electrodes 30 (see FIG. 2) of the IDT electrode 3 is formed on the piezoelectric layer 62.

### (1.2) Support Substrate

The support substrate 7 includes the first main surface 71 and the second main surface 72 that face each other. The first main surface 71 and the second main surface 72 face each other in a thickness direction of the piezoelectric substrate 2g (first direction D1). In a plan view from the thickness direction of the piezoelectric substrate 2g (first direction D1), the support substrate 7 has a rectangular or substantially rectangular shape, but is not limited thereto, and may have a square or substantially square shape, for example.

In the support substrate 7, an acoustic velocity of the bulk wave propagating through the support substrate 7 is higher than an acoustic velocity of the acoustic wave propagating through the piezoelectric layer 62. Here, the bulk wave propagating through the support substrate 7 is a bulk wave having the lowest acoustic velocity among a plurality of bulk waves propagating through the support substrate 7.

The support substrate 7 is, for example, a silicon substrate. In a case where the support substrate 7 is a silicon substrate, the plane orientation of the first main surface 71 of the support substrate 7 is, for example, a (100) plane, but is not limited thereto, and may be, for example, a (110) plane, a (111) plane, or the like. The propagation orientation of the acoustic wave can be set without being restricted by the plane orientation of the first main surface 71 of the support substrate 7.

The support substrate 7 is not limited to a silicon substrate. The support substrate 7 may include, for example, at least one material selected from the group consisting of silicon, aluminum nitride, aluminum oxide, silicon carbide, silicon nitride, sapphire, lithium tantalate, lithium niobate, quartz, alumina, zirconia, cordierite, mullite, steatite, forsterite, magnesia, and diamond.

### (1.3) Piezoelectric Layer

The piezoelectric layer 62 has the first main surface 621 and the second main surface 622 that face each other. The first main surface 621 and the second main surface 622 face each other in the thickness direction of the piezoelectric substrate 2g (first direction D1).

The piezoelectric layer 62 is made of, for example, a Γ° Y-cut X-propagation LiTaO₃ piezoelectric single crystal. When three crystal axes of a LiTaO₃ piezoelectric single crystal are defined as an X-axis, a Y-axis, and a Z-axis, the Γ° Y-cut X-propagation LiTaO₃ piezoelectric single crystal is a LiTaO₃ single crystal obtained by cutting the LiTaO₃ piezoelectric single crystal along a plane having, as a normal line, an axis that is rotated by Γ° about the X-axis as the center axis from the Y-axis in a Z-axis direction, and a surface acoustic wave in the single crystal being propagating in an X-axis direction. The cut angle of the piezoelectric layer 62 is, for example, Γ=θ+90° when the cut angle is Γ[°] and the Euler angles of the piezoelectric layer 62 are (φ, θ, ψ). However, Γ and Γ±180×n are synonymous (crystallographically equivalent). Here, n is a natural number. The piezoelectric layer 62 is not limited to the Γ° Y-cut X-propagation LiTaO₃ piezoelectric single crystal, and may be, for example, a Γ° Y-cut X-propagation LiTaO₃ piezoelectric ceramics.

The thickness of the piezoelectric layer 62 is, for example, equal to or less than about 3.5 λ, where λ is the wavelength of an acoustic wave determined by the electrode finger pitch P1 (see FIG. 2) of the IDT electrode 3. When the thickness of the piezoelectric layer 62 is equal to or less than about 3.5 λ, the Q value of the acoustic wave device 1g is high. In addition, by setting the thickness of the piezoelectric layer 62 to be, for example, equal to or less than about 2.5 λ, the TCF can be reduced. Furthermore, by setting the thickness of the piezoelectric layer 62 to be, for example, equal to or less than about 1.5 λ, it is easy to adjust the acoustic velocity of the acoustic wave. The thickness of the piezoelectric layer 62 is not limited to equal to or less than about 3.5 λ, and may be greater than about 3.5 λ.

When the thickness of the piezoelectric layer 62 is equal to or less than about 3.5 λ, the Q value of the acoustic wave device 1g increases as described above, but a higher-order mode occurs. In the acoustic wave device 1g, the low acoustic velocity film 8 described above is provided so as to reduce the higher-order mode even when the thickness of the piezoelectric layer 62 is equal to or less than about 3.5 λ.

In the acoustic wave device 1g, modes of acoustic waves propagating through the piezoelectric layer 62 include, for example, longitudinal waves, SH waves, SV waves, or a mode in which these waves are combined. In the acoustic wave device 1g, a mode having, for example, an SH wave as a main component is used as a main mode. The higher-order mode is a spurious mode generated on a higher frequency side than the main mode of the acoustic wave propagating through the piezoelectric layer 62. Whether or not the mode of the acoustic wave propagating through the piezoelectric layer 62 is the “main mode in which the main component is an SH wave” can be confirmed by analyzing the strain by analyzing the distribution of displacements by the finite element method using parameters such as the parameters (material, Euler angles, thicknesses, etc.) of the piezoelectric layer 62, the parameters (material, thicknesses, electrode finger pitch P1, etc.) of the IDT electrode 3, and the parameters (material, thicknesses, etc.) of the low acoustic velocity film 8, for example. The Euler angle of the piezoelectric layer 62 can be obtained by analysis.

The material of the piezoelectric layer 62 is not limited to lithium tantalate (LiTaO₃), and may be, for example, lithium niobate (LiNbO₃), zinc oxide (ZnO), aluminum nitride (AlN), or lead zirconate titanate (PZT). In a case where the piezoelectric layer is made of, for example, a Y-cut X-propagation LiNbO₃ piezoelectric single crystal or a piezoelectric ceramics, the acoustic wave device 1g can use an SH mode having a higher coupling coefficient. The single crystal material and the cut angle of the piezoelectric layer 62 may be appropriately determined in accordance with, for example, the required specifications of the filter (filter characteristics such as bandpass characteristics, attenuation characteristics, temperature characteristics, and band width).

### (1.4) Low Acoustic Velocity Film

The low acoustic velocity film 8 is a film such that the acoustic velocity of the bulk wave propagating through the low acoustic velocity film 8 is lower than the acoustic velocity of the bulk wave propagating through the piezoelectric layer 62.

In the acoustic wave device 1g according to Preferred Embodiment 3, the low acoustic velocity film 8 is provided between the support substrate 7 and the piezoelectric layer 62. Since the low acoustic velocity film 8 is provided between the support substrate 7 and the piezoelectric layer 62, the acoustic velocity of the acoustic wave is reduced. The acoustic wave has a property that energy is concentrated in a medium having an essentially low acoustic velocity. Therefore, it is possible to improve the effect of confining the energy of the acoustic wave in the piezoelectric layer 62 and in the IDT electrode 3 in which the acoustic wave is excited. As a result, compared to the case where the low acoustic velocity film 8 is not provided, the loss of the acoustic wave device 1g can be reduced and the Q value of the acoustic wave device 1g can be increased.

The material of the low acoustic velocity film 8 is, for example, silicon oxide. Note that the material of the low acoustic velocity film 8 is not limited to silicon oxide, and may be, for example, glass, silicon oxynitride, tantalum oxide, a compound obtained by adding fluorine, carbon, or boron to silicon oxide, or a material including any of the above-described materials as a main component.

When the low acoustic velocity film 8 is silicon oxide, the temperature characteristics can be improved. The elastic constant of lithium tantalate has a negative temperature characteristic, and silicon oxide has a positive temperature characteristic. Therefore, in the acoustic wave device 1g, the absolute value of the TCF can be reduced.

The thickness of the low acoustic velocity film 8 is preferably, for example, equal to or less than about 2.0 λ, where λ is the wavelength of the acoustic wave determined by the electrode finger pitch P1 described above. The thickness of the low acoustic velocity film 8 is, for example, about 670 nm. By setting the thickness of the low acoustic velocity film 8 to equal to or less than about 2.0 λ, the film stress can be reduced, as a result, the warpage of a silicon wafer that is the base of the support substrate 7 can be reduced when the acoustic wave device 1e is manufactured, and the yield rate can be improved and characteristics can be stabilized.

In addition, in the acoustic wave device 1g, the piezoelectric substrate 2g may include, for example, a close contact layer interposed between the low acoustic velocity film 8 and the piezoelectric layer 62. Thus, the close contact property between the low acoustic velocity film 8 and the piezoelectric layer 62 can be improved. The close contact layer is made of, for example, resin (epoxy resin, polyimide resin, or the like), metal, or the like. In addition, in the acoustic wave device 1g, the piezoelectric substrate 2g includes the close contact layer but not limited thereto, and may include a dielectric film between the low acoustic velocity film 8 and the piezoelectric layer 62, on the piezoelectric layer 62, or under the low acoustic velocity film 8.

### (2) Advantageous Effects

The acoustic wave device 1g according to Preferred Embodiment 3 has a three-layer structure including the piezoelectric layer 62, the low acoustic velocity film 8, and the support substrate 7. Thus, in the acoustic wave device 1g, the effect of confining the acoustic wave energy in the piezoelectric layer 62 and the IDT electrode 3 in which the acoustic wave is excited can be improved due to the property that the energy is concentrated in the medium in which the acoustic wave has an essentially low acoustic velocity. As a result, the Q value of the acoustic wave device 1g can be increased as compared to a case where the low acoustic velocity film 8 is not included.

### (3) Modification

Hereinafter, modifications of Preferred Embodiment 3 will be described.

As Modification 1 of Preferred Embodiment 3, similarly to Modification 1 of Preferred Embodiment 1, each of the electrode fingers 32 of the acoustic wave device 1g may include the plurality of hollow portions 37a (see FIG. 4A).

As Modification 2 of Preferred Embodiment 3, similarly to Modification 2 of Preferred Embodiment 1, each of the electrode fingers 32 of the acoustic wave device 1g may include the hollow portion 37b in which the distal end side of the electrode finger 32 is open (see FIG. 4B).

As Modification 3 of Preferred Embodiment 3, similarly to Modification 3 of Preferred Embodiment 1, each of the electrode fingers 32 of the acoustic wave device 1g may include the hollow portions 371 to 373 having different sizes (see FIG. 4C).

As Modification 4 of Preferred Embodiment 3, similarly to Modification 4 of Preferred Embodiment 1, each of the electrode fingers 32 of the acoustic wave device 1g may include a lower layer, an intermediate layer, and an upper layer that are made of different materials from each other (see FIG. 4D).

As Modification 5 of Preferred Embodiment 3, similarly to Modification 5 of Preferred Embodiment 1, each of the electrode fingers 32 of the acoustic wave device 1g may include the first portion 34 and the plurality of second portion 35 (see FIG. 5).

The acoustic wave device 1g according to the above-described modifications also has the same or substantially the same advantageous effects as those of the acoustic wave device 1g according to Preferred Embodiment 3.

### Preferred Embodiment 4

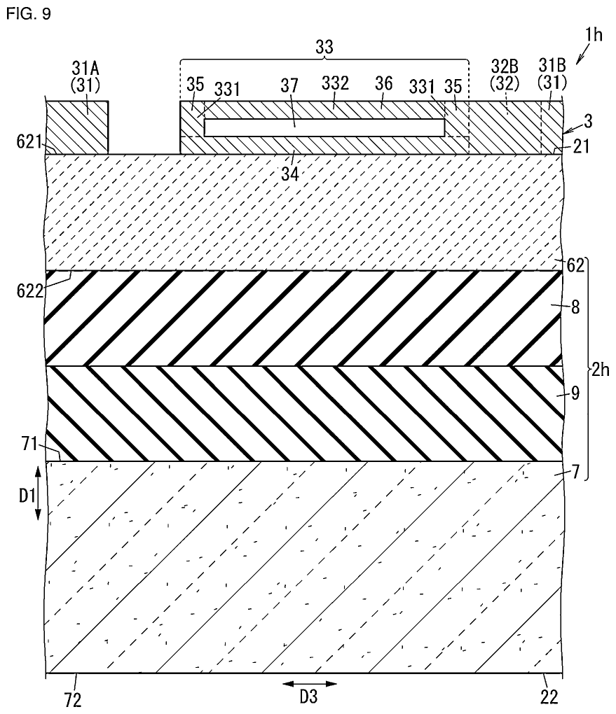

As illustrated in FIG. 9, an acoustic wave device 1h according to Preferred Embodiment 4 of the present invention is different from the acoustic wave device 1g according to Preferred Embodiment 3 (see FIG. 8) in that the acoustic wave device 1h includes the support substrate 7 and a high acoustic velocity film 9. Note that in the acoustic wave device 1h according to Preferred Embodiment 4, the same or corresponding components as those of the acoustic wave device 1g according to Preferred Embodiment 3 are denoted by the same reference numerals, and description thereof will be omitted.

### (1) Configuration

As illustrated in FIG. 9, the acoustic wave device 1h according to Preferred Embodiment 4 includes a piezoelectric substrate 2h and the IDT electrode 3. In other words, the acoustic wave device 1h according to Preferred Embodiment 4 includes the piezoelectric substrate 2h, instead of the piezoelectric substrate 2g of Preferred Embodiment 3 (see FIG. 8).

### (1.1) Piezoelectric Substrate

As illustrated in FIG. 9, the piezoelectric substrate 2h of Preferred Embodiment 4 includes the support substrate 7, the high acoustic velocity film 9, the low acoustic velocity film 8, and the piezoelectric layer 62. The high acoustic velocity film 9 is laminated between the low acoustic velocity film 8 and the support substrate 7.

### (1.2) High Acoustic Velocity Film

As illustrated in FIG. 9, the high acoustic velocity film 9 is provided between the support substrate 7 and the low acoustic velocity film 8. Here, the high acoustic velocity film 9 is provided on the support substrate 7. “Being provided on the support substrate 7” includes a case of being provided directly on the support substrate 7 and a case of being provided indirectly on the support substrate 7.

The high acoustic velocity film 9 is a film in which the acoustic velocity of a bulk wave propagating through the high acoustic velocity film 9 is higher than the acoustic velocity of an acoustic wave propagating through the piezoelectric layer 62. The thicknesses of the high acoustic velocity film 9 are, for example, about 200 nm, about 300 nm, and about 400 nm.

The high acoustic velocity film 9 reduces or prevents leakage of the energy of the acoustic wave in the main mode to a structure below the high acoustic velocity film 9. In the acoustic wave device 1h, when the high acoustic velocity film 9 is sufficiently thick, the energy of the acoustic wave in the main mode is distributed throughout the entire or substantially the entire piezoelectric layer 62 and the low acoustic velocity film 8, is also distributed to a portion of the high acoustic velocity film 9 on the low acoustic velocity film 8 side, and is not distributed to the support substrate 7. The mechanism in which the acoustic wave is confined by the high acoustic velocity film 9 is the same or substantially the same as the case of the surface acoustic wave of the Love wave type that is a non-leakage SH wave, and is described in, for example, the document “Introduction to Surface Acoustic Wave Device Simulation Technology”, Hashimoto Kenya, Realize Co., Ltd., pp. 26-28. This mechanism is different from a mechanism in which an acoustic wave is confined by using a Bragg reflector formed of an acoustic multilayer film.

The material of the high acoustic velocity film 9 is, for example, at least one material selected from the group consisting of diamond-like carbon, aluminum nitride, aluminum oxide, silicon carbide, silicon nitride, silicon, sapphire, a piezoelectric body (lithium tantalate, lithium niobate, or quartz crystal), alumina, zirconia, cordierite, mullite, steatite, forsterite, magnesia, and diamond. The material of the high acoustic velocity film 9 may be a material including any of the above-described materials as a main component or a material including, as a main component, a mixture including any of the above-described materials.

With respect to the thickness of the high acoustic velocity film 9, since the high acoustic velocity film 9 has a function of confining an acoustic wave in the piezoelectric layer 62 and the low acoustic velocity film 8, it is preferable that the thickness of the high acoustic velocity film 9 is as thick as possible. The piezoelectric substrate 2h may include, for example, a close contact layer, a dielectric layer, or the like as a film other than the high acoustic velocity film 9, the low acoustic velocity film 8, and the piezoelectric layer 62.

### (1.3) Support Substrate

The material of the support substrate 7 is, for example, silicon. The material of the support substrate 7 is not limited to silicon, and may be a piezoelectric body such as, for example, sapphire, lithium tantalate, lithium niobate, or quartz, various ceramics such as alumina, magnesia, silicon nitride, aluminum nitride, silicon carbide, zirconia, cordierite, mullite, steatite, or forsterite, a dielectric body such as glass, a semiconductor such as gallium nitride, or a resin.

### (1.4) Low Acoustic Velocity Film

The low acoustic velocity film 8 is provided on the high acoustic velocity film 9. Here, “being provided on the high acoustic velocity film 9” includes a case of being provided directly on the high acoustic velocity film 9 and a case of being provided indirectly on the high acoustic velocity film 9. In the low acoustic velocity film 8, the acoustic velocity of the bulk wave propagating through the low acoustic velocity film 8 is lower than the acoustic velocity of the bulk wave propagating through the piezoelectric layer 62.

### (1.5) Piezoelectric Layer

The piezoelectric layer 62 is provided on the low acoustic velocity film 8. Here, “being provided on the low acoustic velocity film 8” includes a case of being provided directly on the low acoustic velocity film 8 and a case of being provided indirectly on the low acoustic velocity film 8.

### (2) Advantageous Effects

The acoustic wave device 1h according to Preferred Embodiment 4 has a four-layer structure including the piezoelectric layer 62, the low acoustic velocity film 8, the high acoustic velocity film 9, and the support substrate 7. Accordingly, it is possible to reduce or prevent leakage of the energy of the acoustic wave to the support substrate 7, and thus the Q value of the acoustic wave device 1h can be further improved.

### (3) Modification

As Modification 1 of Preferred Embodiment 4, similarly to Modification 1 of Preferred Embodiment 1, each of the electrode fingers 32 of the acoustic wave device 1h may include the plurality of hollow portions 37a (see FIG. 4A).

As Modification 2 of Preferred Embodiment 4, similarly to Modification 2 of Preferred Embodiment 1, each of the electrode fingers 32 of the acoustic wave device 1h may include the hollow portion 37b in which the distal end side of the electrode finger 32 is open (see FIG. 4B).

As Modification 3 of Preferred Embodiment 4, similarly to Modification 3 of Preferred Embodiment 1, each of the electrode fingers 32 of the acoustic wave device 1h may include the hollow portions 371 to 373 having different sizes (see FIG. 4C).

As Modification 4 of Preferred Embodiment 4, similarly to Modification 4 of Preferred Embodiment 1, each of the electrode fingers 32 of the acoustic wave device 1h may include a lower layer, an intermediate layer, and an upper layer that are made of different materials from each other (see FIG. 4D).

As Modification 5 of Preferred Embodiment 4, similarly to Modification 5 of Preferred Embodiment 1, each of the electrode fingers 32 of the acoustic wave device 1h may include the first portion 34 and the plurality of second portion 35 (see FIG. 5).

The acoustic wave device 1h according to the above-described modifications also has the same or substantially the same effects as those of the acoustic wave device 1h according to Preferred Embodiment 4.

The preferred embodiments and modifications described above are only a portion of various preferred embodiments and modifications of the present invention. In addition, the preferred embodiments and modifications can be variously changed according to design or the like as long as the object of the present invention can be achieved.

The following aspects are disclosed herein.

An acoustic wave device (1; 1a to 1e; 1f; 1g; 1h) according to a preferred embodiment of the present invention includes a piezoelectric substrate (2; 2f; 2g; 2h) and an IDT electrode (3; 3a to 3e). The IDT electrode (3; 3a to 3e) is provided on the piezoelectric substrate (2; 2f; 2g; 2h). The IDT electrode (3; 3a to 3e) includes a plurality of electrode fingers (32) and a busbar (31). The plurality of electrode fingers (32) are connected to the busbar (31). At least one electrode finger (32) of the plurality of electrode fingers (32) includes a first portion (34; 34c; 34d) and a second portion (35; 35a to 35d) in an intersection region (33) where the plurality of electrode fingers (32) overlap each other when viewed from a propagation direction (second direction D2) of an acoustic wave in the piezoelectric substrate (2; 2f; 2g; 2h). The first portion (34; 34c; 34d) is in direct contact with the piezoelectric substrate (2; 2f; 2g; 2h). The second portion (35; 35a to 35d) is laminated on the first portion (34; 34c; 34d). The second portion (35; 35a to 35d) is located on the first portion (34; 34c; 34d) such that a space (hollow portion 37; 371 to 373) in at least a portion of a central portion (333) of the intersection region (33) in the first portion (34; 34c; 34d) is provided. A thickness (δ1) of the first portion (34; 34c; 34d) is thinner than a thickness (δ3) of the busbar (31). The sum of the thickness (δ1) of the first portion (34; 34c; 34d) in a portion (first portion 331) where the second portion (35; 35a to 35d) is present and a thickness (δ2) of the second portion (35; 35a to 35d) is thicker than the thickness (δ1) of the first portion (34; 34c; 34d) in a portion (second portion 332) where the second portion (35; 35a to 35d) is not present.

According to the above-described acoustic wave device (1; 1a to 1e; 1f; 1g; 1h), it is possible to improve both the Q value at the resonant frequency and the Q value at the anti-resonant frequency.

In an acoustic wave device (1; 1a to 1e; 1f; 1g; 1h) according to a preferred embodiment of the present invention, the at least one electrode finger (32) further includes a third portion (36; 36a to 36d). The third portion (36; 36a to 36d) extends from the second portion (35; 35a to 35d) over at least a portion of the central portion (333) of the intersection region (33) in a plan view from the thickness direction (first direction D1) of the piezoelectric substrate (2; 2f; 2g; 2h).

According to the above-described acoustic wave device (1; 1a to 1e; 1f; 1g; 1h), since the volume of the entire IDT electrode (3; 3a to 3d) can be increased, the resistance loss can be further reduced. As a result, the Q value at the resonant frequency can be further improved.

In an acoustic wave device (1; 1c to 1e; 1f; 1g; 1h) according to a preferred embodiment of the present invention, the at least one electrode finger (32) includes a plurality of the second portions (35; 35c; 35d). In a plan view from the thickness direction (first direction D1) of the piezoelectric substrate (2; 2f; 2g; 2h), the total area of portions between the plurality of second portions (35; 35c; 35d) is larger than the total area of the plurality of second portions (35; 35c; 35d).

According to the above-described acoustic wave device (1; 1c to 1e; 1f; 1g; 1h), the Q value at the resonant frequency and the Q value at the anti-resonant frequency can be further improved.

In an acoustic wave device (1; 1a; 1c to 1e; 1f; 1g; 1h) according to a preferred embodiment of the present invention, the second portion (35; 35a; 35c; 35d) is provided in an edge portion (tip side portion 334) in an outer side portion of the central portion (333) in the intersection region (33).

According to the above-described acoustic wave device (1; 1a; 1c to 1e; 1f; 1g; 1h), the second portion (35; 35a; 35c; 35d) is a low acoustic velocity region and a piston mode can be provided, such that transverse mode ripple can be reduced or prevented.

In an acoustic wave device (1; 1a to 1e; 1f; 1g; 1h) according to a preferred embodiment of the present invention, the second portion (35; 35a to 35d) includes aluminum.

According to the above-described acoustic wave device (1; 1a to 1e; 1f; 1g; 1h), the electrical conductivity of the IDT electrode (3; 3a to 3e) can be improved.

In an acoustic wave device (1; 1a to 1e; 1f; 1g; 1h) according to a preferred embodiment of the present invention, the third portion (36; 36a to 36d) includes aluminum.

According to the above-described acoustic wave device (1; 1a to 1e; 1f; 1g; 1h), the electrical conductivity of the IDT electrode (3; 3a to 3e) can be improved.

In an acoustic wave device (1f; 1g; 1h) according to a preferred embodiment of the present invention, the piezoelectric substrate (2f; 2g; 2h) includes a piezoelectric layer (62) and a support substrate (7). The support substrate (7) is laminated on the piezoelectric layer (62).

According to the above-described acoustic wave device (1f; 1g; 1h), since an acoustic wave energy can be confined in the piezoelectric layer (62) and the IDT electrode (3) in which an acoustic wave is excited, the Q value of the acoustic wave device (1f; 1g; 1h) can be improved.

In an acoustic wave device (1g; 1h) according to a preferred embodiment of the present invention, the piezoelectric substrate (2g; 2h) further includes a low acoustic velocity film (8). The low acoustic velocity film (8) is laminated between the piezoelectric layer (62) and the support substrate (7). In the low acoustic velocity film (8), an acoustic velocity of a bulk wave propagating through the low acoustic velocity film (8) is lower than an acoustic velocity of a bulk wave propagating through the piezoelectric layer (62).

According to the above-described acoustic wave device (1g; 1h), the effect of confining the acoustic wave energy in the piezoelectric layer (62) and in the IDT electrode (3) in which the acoustic wave is excited can be improved by the property that the energy is concentrated in the medium in which the acoustic wave has an essentially low acoustic velocity. As a result, the Q value of the acoustic wave device (1g; 1h) can be further increased as compared to a case where the low acoustic velocity film (8) is not included.

In an acoustic wave device (1h) according to a preferred embodiment of the present invention, the piezoelectric substrate (2h) further includes a high acoustic velocity film (9). The high acoustic velocity film (9) is laminated between the low acoustic velocity film (8) and the support substrate (7). In the high acoustic velocity film (9), the acoustic velocity of a bulk wave propagating through the high acoustic velocity film (9) is higher than the acoustic velocity of an acoustic wave propagating through the piezoelectric layer (62).

According to the above-described acoustic wave device (1h), since it is possible to reduce or prevent leakage of the energy of the acoustic wave to the support substrate (7), the Q value of the acoustic wave device (1h) can be further improved.

In an acoustic wave device (1; 1a to 1e; 1f; 1g; 1h) according to a preferred embodiment of the present invention, a thickness of the piezoelectric substrate (2; 2f; 2g; 2h) is less than about 2 λ where λ is a wavelength determined by a pitch (P1) of the plurality of electrode fingers (32) of the IDT electrode (3; 3a to 3e).

According to the above-described acoustic wave device (1; 1a to 1e; 1f; 1g; 1h), it is possible to further improve the Q value of the acoustic wave device (1; 1a to 1e; 1f; 1g; 1h).

In an acoustic wave device (1; 1a to 1e; 1f; 1g; 1h) according to a preferred embodiment of the present invention, the second portion (35; 35a to 35d) is laminated on a portion (tip side portion 334; base side portion 335) of the first portion (34; 34c; 34d) different from the central portion (333).

In an acoustic wave device (1a; 1c) according to a preferred embodiment of the present invention, the at least one electrode finger (32) includes a plurality of the second portion (35a; 35c). At least one of the plurality of second portion (35a; 35c) is laminated on a portion of the first portion (34; 34c) different from the central portion (333). At least one of the remainder of the plurality of second portion (35a; 35c) is laminated on the central portion (333) of the first portion (34; 34c).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate; and
an IDT electrode on the piezoelectric substrate; wherein
the IDT electrode includes:
a plurality of electrode fingers; and
a busbar to which the plurality of electrode fingers are connected;
at least one electrode finger of the plurality of electrode fingers includes:
in an intersection region at which the plurality of electrode fingers overlap each other when viewed from a propagation direction of an acoustic wave in the piezoelectric substrate;
a first portion in direct contact with the piezoelectric substrate; and
a second portion on the first portion;
the second portion is located on the first portion such that a space in at least a portion of a central portion of the intersection region in the first portion is provided;
a thickness of the first portion is thinner than a thickness of the busbar; and
a sum of a thickness of the first portion in a portion where the second portion is present and a thickness of the second portion is thicker than a thickness of the first portion in a portion where the second portion is not present.

2. The acoustic wave device according to claim 1, wherein
the at least one electrode finger further includes a third portion extending from the second portion over at least a portion of the central portion of the intersection region in a plan view from a thickness direction of the piezoelectric substrate.

3. The acoustic wave device according to claim 1, wherein
the at least one electrode finger includes a plurality of the second portions; and
in a plan view from a thickness direction of the piezoelectric substrate, a total area of portions between the plurality of second portions is larger than a total area of the plurality of second portions.

4. The acoustic wave device according to claim 1, wherein the second portion is at an edge portion outside the central portion in the intersection region.

5. The acoustic wave device according to claim 1, wherein the second portion includes aluminum.

6. The acoustic wave device according to claim 2, wherein the third portion includes aluminum.

7. The acoustic wave device according to claim 1, wherein
the piezoelectric substrate includes:
a piezoelectric layer; and
a support substrate on the piezoelectric layer.

8. The acoustic wave device according to claim 7, wherein the piezoelectric substrate further includes a low acoustic velocity film between the piezoelectric layer and the support substrate, an acoustic velocity of a bulk wave propagating through the low acoustic velocity film being lower than an acoustic velocity of a bulk wave propagating through the piezoelectric layer.

9. The acoustic wave device according to claim 8, wherein the piezoelectric substrate further includes a high acoustic velocity film between the low acoustic velocity film and the support substrate, an acoustic velocity of a bulk wave propagating through the high acoustic velocity film being higher than an acoustic velocity of an acoustic wave propagating through the piezoelectric layer.

10. The acoustic wave device according to claim 1, wherein a thickness of the piezoelectric substrate is less than about 2 λ, where λ is a wavelength determined by a pitch of the plurality of electrode fingers of the IDT electrode.

11. The acoustic wave device according to claim 1, wherein the second portion is located on a portion of the first portion that is different from the central portion.

12. The acoustic wave device according to claim 1, wherein
the at least one electrode finger includes a plurality of the second portions;
at least one of the plurality of second portions is on a portion of the first portion different from the central portion; and
at least one of a remainder of the plurality of second portions on the central portion of the first portion.

13. The acoustic wave device according to claim 2, wherein
the at least one electrode finger includes a plurality of the second portions; and
in a plan view from a thickness direction of the piezoelectric substrate, a total area of portions between the plurality of second portions is larger than a total area of the plurality of second portions.

14. The acoustic wave device according to claim 2, wherein the second portion is at an edge portion outside the central portion in the intersection region.

15. The acoustic wave device according to claim 2, wherein the second portion includes aluminum.

16. The acoustic wave device according to claim 2, wherein
the piezoelectric substrate includes:
a piezoelectric layer; and
a support substrate on the piezoelectric layer.

17. The acoustic wave device according to claim 16, wherein the piezoelectric substrate further includes a low acoustic velocity film between the piezoelectric layer and the support substrate, an acoustic velocity of a bulk wave propagating through the low acoustic velocity film being lower than an acoustic velocity of a bulk wave propagating through the piezoelectric layer.

18. The acoustic wave device according to claim 17, wherein the piezoelectric substrate further includes a high acoustic velocity film between the low acoustic velocity film and the support substrate, an acoustic velocity of a bulk wave propagating through the high acoustic velocity film being higher than an acoustic velocity of an acoustic wave propagating through the piezoelectric layer.
